(19) United States
(12) Patent Application Publication
(10) Pub. No.: US 2026/0305466 A1
(43) Pub. Date: Oct. 1, 2026

(54) POWER DEVICE PACKAGE

(71) Applicant: GaNrich Semiconductor Corporation, Hsinchu County (TW)

(72) Inventors: Sheng-Po Wang, Taoyuan City (TW); Chiao Fu, Hsinchu County (TW); Chen-Yu Wang, Taoyuan City (TW); Jia-Tay Kuo, Hsinchu County (TW)

(73) Assignee: GaNrich Semiconductor Corporation, Hsinchu County (TW)

(21) Appl. No.: 19/199,411

(22) Filed: May 6, 2025

(30) Foreign Application Priority Data
Mar. 25, 2025 (TW) 114111105

(51) Int. Cl. H01L 25/16; H01L 23/00; H01L 23/373; H01L 23/495; H01L 23/522; H01L 23/528

(52) U.S. Cl. CPC H10W 90/00; H10W 20/427; H10W 20/498; H10W 40/258; H10W 70/421; H10W 70/457; H10W 70/465; H10W 70/468; H10W 90/753; H10W 90/755

(57) ABSTRACT

A power device package including: a frame base island; a power device disposed on the frame base island; a molding compound encapsulating the frame base island and the power device; a drain pin extending outward from one side of the frame base island and protruding from the molding compound; a gate pin located on one side of the drain pin, extending and protruding from the molding compound; a source pin located on the other side of the drain pin relative to the gate pin, extending and protruding from the molding compound; and a transfer board device mounted on the frame base island.

### BACKGROUND OF THE INVENTION

### 1. Field of the Invention

The present invention relates to the field of packaging technology for semiconductor power devices, and more particularly to an improved GaN power device package.

### 2. Description of the Prior Art

As known to those skilled in the art, silicon-based MOS power devices (Si MOS power devices) are generally vertical devices where the source and gate electrodes are located on the front side of the chip, and the drain electrode is located on the back side of the chip. When forming, for example, a TO 220 package, the Si MOS power device is attached to a frame island connected to the drain pin using silver epoxy. Then, wires are used to electrically connect the gate and source, located on the front side of the chip, to the corresponding gate pin and source pin, respectively. Taking the TO 220 package as an example, the pin definition from left to right is a GDS configuration, representing Gate (G), Drain (D), and Source(S).

Gallium nitride (GaN) power devices are generally lateral devices, meaning their drain, source, and gate are all located on the front side of the chip. If a GaN power device needs to be co-packaged with a Gate Driver IC, issues arise where the IC device, die-bonded to the frame island, can be damaged due to high-voltage operation.

### SUMMARY OF THE INVENTION

In view of the foregoing, it is one objective of the present disclosure to provide an improved GaN power device package that utilizes a transfer board device, enabling the co-packaging of the GaN power device with a gate driver IC or a low-voltage MOS (LV MOS) device, thereby effectively preventing component damage caused by high-voltage operation.

One aspect of the present disclosure provides a power device package including a frame base island; a power device mounted on the frame base island; a molding compound encapsulating the frame base island and the power device; a drain pin extending outward from one side of the frame base island and protruding from the molding compound; a gate pin located on one side of the drain pin, and extending and protruding from the molding compound; a source pin located on the other side of the drain pin relative to the gate pin, and extending and protruding from the molding compound; and a transfer board device mounted on the frame base island, wherein the transfer board device is electrically connected to the power device, the frame base island, the gate pin, the source pin, or the drain pin via a plurality of bonding wires.

According to some embodiments, the transfer board device comprises a substrate; and an adhesive layer located between the substrate and the frame base island.

According to some embodiments, the substrate comprises a ceramic substrate, an aluminum substrate, or an FR4 glass fiber substrate.

According to some embodiments, the adhesive layer comprises silver paste.

According to some embodiments, the transfer board device comprises an insulating layer located on the substrate; a patterned copper circuit layer located on the insulating layer; and a protective layer covering the insulating layer and the periphery of the patterned copper circuit layer.

According to some embodiments, a thickness of the transfer board device is between 0.1 mm and 1.0 mm.

According to some embodiments, the power device is a GaN power device.

According to some embodiments, the GaN power device comprises a D-Mode GaN HEMT die.

According to some embodiments, the power device package further comprising a low-voltage, silicon-based MOS die disposed on the transfer board device; and a resistor element disposed on the transfer board device.

According to some embodiments, the resistor element is fixed onto the transfer board device using surface mount technology.

According to some embodiments, the patterned copper circuit layer comprises a separated first trace and a second trace, and the resistor element bridges the first trace and the second trace.

According to some embodiments, the low-voltage, silicon-based MOS die is die-bonded onto the first trace.

According to some embodiments, the power device package further comprising a gate driver component disposed on the transfer board device.

According to some embodiments, the GaN power device comprises an E-Mode GaN HEMT die.

According to some embodiments, the frame base island is connected to a heat sink.

According to some embodiments, the frame base island, the heat sink, and the drain pin are integrally formed from copper metal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

To facilitate easier understanding of the following description, it is recommended to refer to the drawings and their detailed textual explanations while reading this disclosure. Specific embodiments of the present disclosure will be explained in detail through the specific embodiments herein and with reference to the corresponding drawings, thereby elucidating the working principles of the embodiments of the present disclosure. Furthermore, for clarity, the various features in the drawings may not be drawn to actual scale, and thus the dimensions of some features in certain drawings may be intentionally enlarged or reduced.

FIG. 1 is a partial perspective view illustrating a GaN power device package according to an embodiment of the present invention.

FIG. 2 is a schematic cross-sectional view taken along the line I-I′ shown in FIG. 1.

FIG. 3 illustrates a cascode circuit diagram of the GaN power device package in FIG. 1.

FIG. 4 is a partial perspective view illustrating a GaN power device package according to another embodiment of the present invention.

FIG. 5 illustrates a circuit diagram of the GaN power device package in FIG. 4.

FIG. 6 is a partial perspective view illustrating a GaN power device package according to still another embodiment of the present invention.

FIG. 7 is a schematic cross-sectional view taken along the line II-II′ shown in FIG. 6.

### DETAILED DESCRIPTION

The present disclosure provides several different embodiments that can be used to implement various features of the disclosure. For the sake of simplifying the description, the present disclosure also describes examples of specific components and arrangements. These embodiments are provided for illustrative purposes only and are not intended to be limiting. For example, the description below regarding “a first feature formed on or above a second feature” can mean “the first feature is in direct contact with the second feature,” or it can also mean “other features are interposed between the first feature and the second feature,” such that the first feature and the second feature are not in direct contact. Furthermore, various embodiments in the present disclosure may use repeated reference numerals and/or textual annotations. The use of these repeated reference numerals and annotations is for the purpose of making the description simpler and clearer, and not to indicate a relationship between different embodiments and/or configurations.

Additionally, regarding the spatial terms mentioned in this disclosure, such as “below,” “lower,” “under,” “above,” “upper,” “down,” “top,” “bottom,” and similar terms, they are used for descriptive convenience to describe the relative relationship of one element or feature to another element or feature in the drawings. These spatial terms are also intended to encompass different orientations of the semiconductor device in use and operation, in addition to the orientation shown in the drawings. As the orientation of the semiconductor device may vary (rotated by 90 degrees or other orientations), the spatially relative descriptors used to describe its orientation should be interpreted accordingly in a similar manner.

Although the present disclosure uses terms such as first, second, and third to describe various elements, components, regions, layers, and/or sections, it should be understood that these elements, components, regions, layers, and/or sections should not be limited by these terms. These terms are only used to distinguish one element, component, region, layer, and/or section from another element, component, region, layer, and/or section, and do not inherently represent any preceding ordinal number for the element, nor do they represent an arrangement order or a manufacturing order between one element and another. Thus, without departing from the scope of the embodiments of the present disclosure, the first element, component, region, layer, or section discussed below could also be termed a second element, component, region, layer, or section.

The terms “about” or “substantially” as referred to herein generally indicate a range within 20%, preferably within 10%, and more preferably within 5%, or 3%, or 2%, or 1%, or 0.5% of a given value or range. It should be noted that the quantities provided in the specification are approximate quantities, meaning that the terms “about” or “substantially” can still be implied even if not specifically stated.

Although the following description illustrates the present disclosure by way of specific embodiments, the inventive principles of the present disclosure are also applicable to other embodiments. Furthermore, in order to avoid obscuring the spirit of the present invention, certain details will be omitted, as these omitted details fall within the knowledge scope of those skilled in the art.

Group III-V (e.g., gallium nitride) High Electron Mobility Transistors (HEMTs) can be classified into two types: Enhancement-Mode HEMTs (E-Mode HEMTs) and Depletion-Mode HEMTs (D-Mode HEMTs). Common HEMT package types include Transistor Outline packages (TO), Dual Flat No-lead packages (DFN), and Quad Flat No-lead packages (QFN). The following embodiments are described using the TO 220 package as an example only. However, those skilled in the art should understand that the present invention can also be applied to other types of package leadframe structures, such as TO247, DFN8x8, DFN5x6, QFN8x8, QFN5x6, and other package carriers.

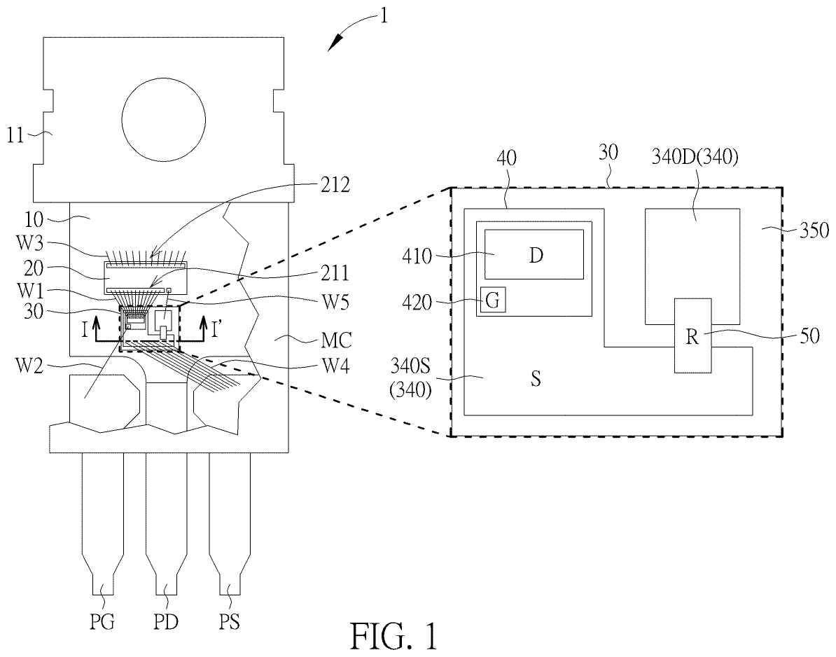

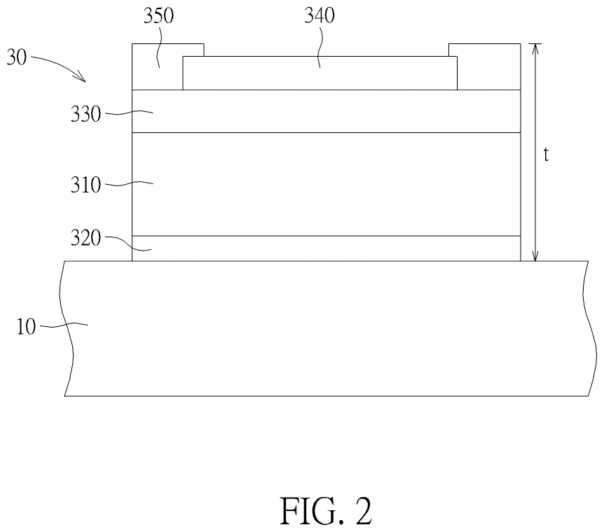

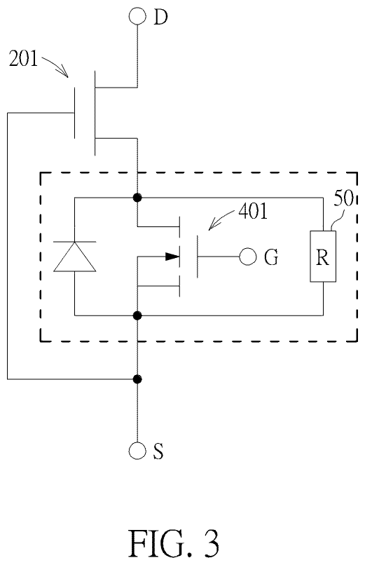

Please refer to FIGS. 1-3, wherein FIG. 1 is a partial perspective view illustrating a GaN power device package according to an embodiment of the present invention, FIG. 2 is a schematic cross-sectional view taken along the section line I-I′ shown in FIG. 1, and FIG. 3 illustrates a cascode circuit diagram of the GaN power device package in FIG. 1.

As shown in FIGS. 1-3, the GaN power device package 1 includes a frame base island 10, a heat sink 11 connected to the frame base island 10, a drain pin PD extending outward from one side of the frame base island 10, a gate pin PG and a source pin PS respectively located on both sides of the drain pin PD, and a GaN power device 20 mounted on the frame base island 10. According to an embodiment of the present invention, the pin assignment is defined as a GDS configuration of Gate (G), Drain (D), and Source(S) from left to right. According to an embodiment of the present invention, the frame base island 10, the heat sink 11, and the drain pin PD can be integrally formed from copper metal, but are not limited thereto. According to an embodiment of the present invention, the GaN power device 20 is, for example, a D-Mode GaN HEMT die.

According to an embodiment of the present invention, as shown in the partial enlarged view in FIG. 1, the GaN power device package 1 further includes a transfer board device 30, which is mounted on the frame base island 10 and located on one side of the GaN power device 20. According to an embodiment of the present invention, a low-voltage, silicon-based MOS die 40 and a resistor element 50 are further disposed on the transfer board device 30. According to an embodiment of the present invention, both the transfer board device 30 and the resistor element 50 can be fixed onto the transfer board device 30 using surface mount technology. As shown in FIG. 3, a cascode configuration formed by a low-voltage nMOS transistor 401 in the low-voltage silicon-based MOS die 40, a D-Mode GaN transistor 201 in the GaN power device 20, and the resistor element 50 enables normally-off operation. According to an embodiment of the present invention, the frame base island 10, the GaN power device 20, the transfer board device 30, the resistor element 50, a portion of the drain pin PD, a portion of the gate pin PG, and a portion of the source pin PS are encapsulated and protected by a molding compound MC.

According to an embodiment of the present invention, the transfer board device 30 can be a substrate with patterned circuitry thereon, such as a high-temperature resistant substrate like a ceramic substrate, an aluminum substrate, or an FR4 glass fiber substrate, but is not limited thereto. According to an embodiment of the present invention, for example, the ceramic substrate may include aluminum oxide (Al₂O₃) or aluminum nitride (AlN), but is not limited thereto. For example, as shown in FIG. 2, the thickness t of the transfer board device 30 is approximately between 0.1 mm and 1.0 mm, and it can include a substrate 310, an adhesive layer 320 located between the substrate 310 and the frame base island 10, an insulating layer 330 located on the substrate 310, a patterned copper circuit layer 340 located on the insulating layer 330, and a protective layer 350 covering the insulating layer 330 and the periphery of the patterned copper circuit layer 340. According to an embodiment of the present invention, the patterned copper circuit layer 340 includes, for example, a separated first trace 340S and a second trace 340D, and the resistive element 50 is surface-mounted bridging the first trace 340S and the second trace 340D. According to an embodiment of the present invention, the low-voltage, silicon-based MOS die 40 is surface-mounted and die-bonded to the other end of the first trace 340S.

According to some embodiments of the present invention, if the substrate 310 is made of a non-conductive substrate material, such as ceramic or fiberglass, then the insulating layer 330 can be omitted. According to some embodiments of the present invention, the adhesive layer 320 adheres and fixes the substrate 310 onto the frame base island 10. For example, the adhesive layer 320 may comprise silver paste or other adhesive materials capable of withstanding high temperatures of at least 80-90° C.

According to an embodiment of the present invention, after fixing the transfer board device 30 with the low-voltage, silicon-based MOS die 40 and the resistor element 50, and a GaN power device 20 onto the frame base island 10, a wire bonding process is performed. A source pad 211 on the GaN power device 20 is electrically connected to a drain pad 410 on the low-voltage, silicon-based MOS die 40 via a bonding wire W1 (e.g., a copper wire). A gate pad 420 on the low-voltage, silicon-based MOS die 40 is electrically connected to the gate pin PG via a bonding wire W2 (e.g., a copper wire). A drain pad 212 on the GaN power device 20 is electrically connected to the frame base island 10 and the drain pin PD via a bonding wire W3 (e.g., a copper wire). The first trace 340S of the transfer board device 30 is electrically connected to the source pin PS via a bonding wire W4 (e.g., a copper wire), and the second trace 340D of the transfer board device 30 is electrically connected to another source pad 211 on the GaN power device 20 via a bonding wire W5 (e.g., a copper wire), forming a cascode configuration as shown in FIG. 3. Since the low-voltage, silicon-based MOS die 40 is die-bonded onto the transfer board device 30, damage to the low-voltage devices due to high-voltage operation can be avoided.

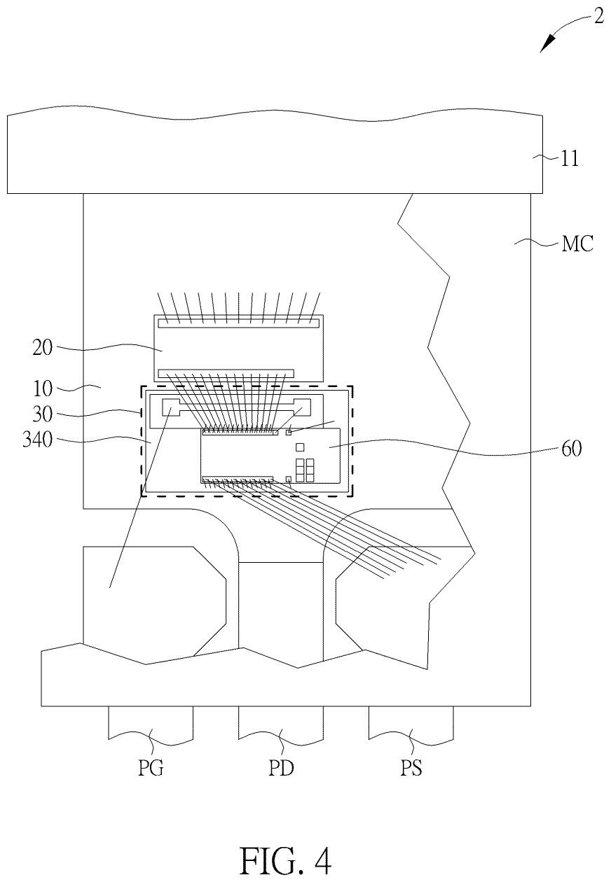

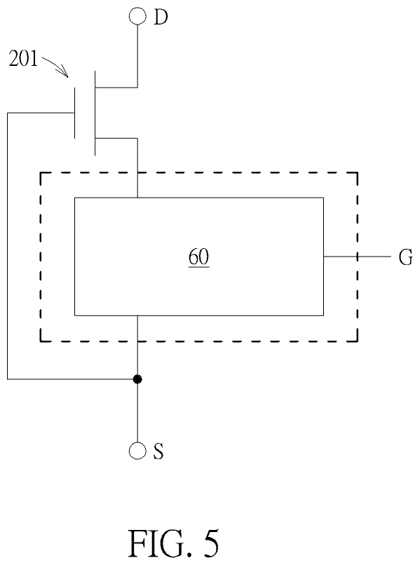

Please refer to FIGS. 4-5, wherein FIG. 4 is a partial perspective view of a GaN power device package according to another embodiment of the present invention, and FIG. 5 illustrates the circuit diagram of the GaN power device package in FIG. 4, where like regions, layers, or elements are designated by like numeral numbers or labels.

As shown in FIGS. 4-5, the GaN power device package 2 includes a frame base island 10, a heat sink 11 connected to the frame base island 10, a drain pin PD extending outward from one side of the frame base island 10, a gate pin PG and a source pin PS respectively located on both sides of the drain pin PD, and a GaN power device 20 mounted on the frame base island 10. According to an embodiment of the present invention, the pin assignment is defined as a GDS configuration of Gate (G), Drain (D), and Source(S) from left to right. According to an embodiment of the present invention, the frame base island 10, the heat sink 11, and the drain pin PD can be made of integrally formed copper metal, but are not limited thereto. According to an embodiment of the present invention, the GaN power device 20 is, for example, a D-Mode GaN HEMT die.

According to an embodiment of the present invention, likewise, the GaN power device package 2 further includes a transfer board device 30, mounted on the frame base island 10 and located on one side of the GaN power device 20. According to an embodiment of the present invention, a gate driver component 60 is mounted on the transfer board device 30. According to an embodiment of the present invention, the gate driver component 60 can be fixed onto the transfer board device 30 using surface mount technology. As shown in FIG. 5, a normally-off operation is achieved through a cascode configuration formed by the gate driver component 60 and the D-Mode GaN transistor 201 in the GaN power device 20. According to an embodiment of the present invention, the frame base island 10, the GaN power device 20, the transfer board device 30, the gate driver component 60, a portion of the drain pin PD, a portion of the gate pin PG, and a portion of the source pin PS are encapsulated and protected by molding compound MC.

According to an embodiment of the present invention, the transfer board device 30 can be a substrate with patterned circuitry, such as a ceramic substrate, an aluminum substrate, or an FR4 glass fiber substrate, but is not limited thereto. According to an embodiment of the present invention, for example, the ceramic substrate can comprise aluminum oxide (Al₂O₃) or aluminum nitride (AlN), but is not limited thereto. For example, the thickness of the transfer board device 30 is between approximately 0.1 mm and 1.0 mm, and its structure is as shown in FIG. 2, which will not be further elaborated upon. According to an embodiment of the present invention, connections between different potential contacts can be made through the patterned copper circuit layer 340 on the transfer board device 30 and the bonding wires.

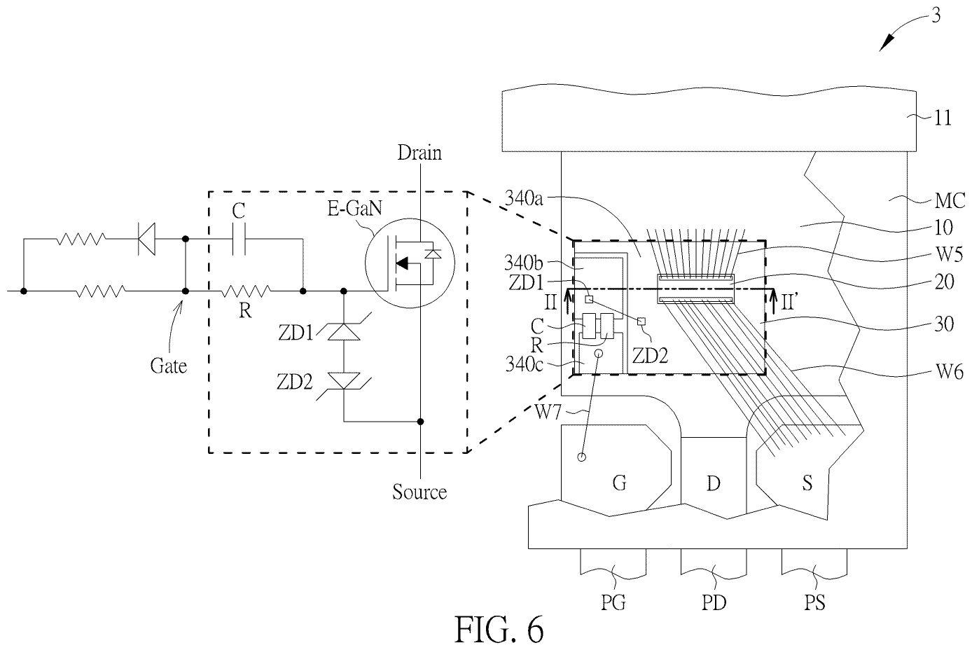

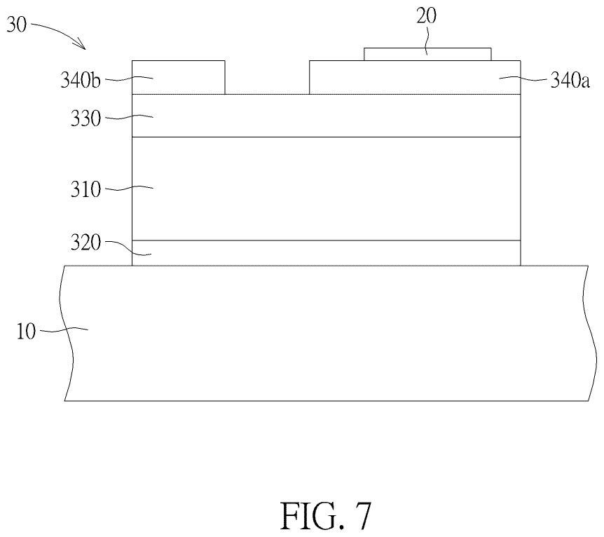

Please refer to FIGS. 6 and 7, wherein FIG. 6 is a partial perspective view of a GaN power device package according to yet another embodiment of the present invention, and FIG. 7 is a schematic cross-sectional view taken along line II-II′ in FIG. 6, wherein like regions, layers, or elements are still designated by like numeral numbers or labels.

As shown in FIGS. 6-7, likewise, the GaN power device package 3 includes a frame base island 10, a heat sink 11 connected to the frame base island 10, a drain pin PD extending outward from one side of the frame base island 10, a gate pin PG and a source pin PS respectively located on both sides of the drain pin PD, and a GaN power device 20 die-bonded onto a transfer board device 30. According to an embodiment of the present invention, the pin assignment is defined as a GDS configuration of Gate (G), Drain (D), and Source(S) from left to right. According to an embodiment of the present invention, the frame base island 10, the heat sink 11, and the drain pin PD can be integrally formed from copper metal, but are not limited thereto. According to an embodiment of the present invention, the GaN power device 20 is, for example, an E-Mode GaN HEMT die. According to an embodiment of the present invention, through bonding wires W5 and W6, the drain pad and the source pad of the GaN power device 20 can be electrically connected to the frame base island 10 and the source pin PS, respectively.

According to an embodiment of the present invention, the transfer board device 30 can be a substrate with patterned circuitry thereon, including, but not limited to, a ceramic substrate, an aluminum substrate, or an FR4 glass fiber substrate. According to an embodiment of the present invention, for example, the ceramic substrate can comprise aluminum oxide (Al₂O₃) or aluminum nitride (AlN), but is not limited thereto. The transfer board device 30 can comprise a patterned copper circuit layer 340a, a patterned copper circuit layer 340b, and a patterned copper circuit layer 340c located on the substrate 310. The patterned copper circuit layer 340a, the patterned copper circuit layer 340b, and the patterned copper circuit layer 340c are not interconnected with each other. On the transfer board device 30, a resistor R and a capacitor C are surface-mounted bridging the patterned copper circuit layer 340b and the patterned copper circuit layer 340c, which, together with diodes ZD1 and ZD2, constitute a protection circuit, as shown in the figure. According to an embodiment of the present invention, the patterned copper circuit layer 340c can be electrically connected to the gate pin PG through a bonding wire W7.

According to some embodiments of the present invention, if the substrate 310 is made of a non-conductive substrate material, such as ceramic or fiberglass, the insulating layer 330 can be omitted. According to embodiments of the present invention, the adhesive layer 320 adheres and fixes the substrate 310 onto the frame base island 10. For example, the adhesive layer 320 may comprise silver paste or other adhesive materials capable of withstanding high temperatures of at least 80-90° C.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A power device package, comprising:
a frame base island;
a power device mounted on the frame base island;
a molding compound encapsulating the frame base island and the power device;
a drain pin extending outward from one side of the frame base island and protruding from the molding compound;
a gate pin located on one side of the drain pin, and extending and protruding from the molding compound;
a source pin located on the other side of the drain pin relative to the gate pin, and extending and protruding from the molding compound; and
a transfer board device mounted on the frame base island, wherein the transfer board device is electrically connected to the power device, the frame base island, the gate pin, the source pin, or the drain pin via a plurality of bonding wires.

2. The power device package according to claim 1, wherein the transfer board device comprises:
a substrate; and
an adhesive layer located between the substrate and the frame base island.

3. The power device package according to claim 2, wherein the substrate comprises a ceramic substrate, an aluminum substrate, or an FR4 glass fiber substrate.

4. The power device package according to claim 2, wherein the adhesive layer comprises silver paste.

5. The power device package according to claim 2, wherein the transfer board device comprises:
an insulating layer located on the substrate;
a patterned copper circuit layer located on the insulating layer; and
a protective layer covering the insulating layer and the periphery of the patterned copper circuit layer.

6. The power device package according to claim 1, wherein a thickness of the transfer board device is between 0.1 mm and 1.0 mm.

7. The power device package according to claim 1, wherein the power device is a GaN power device.

8. The power device package according to claim 7, wherein the GaN power device comprises a D-Mode GaN HEMT die.

9. The power device package according to claim 7, further comprising:
a low-voltage, silicon-based MOS die disposed on the transfer board device; and
a resistor element disposed on the transfer board device.

10. The power device package according to claim 9, wherein the resistor element is fixed onto the transfer board device using surface mount technology.

11. The power device package according to claim 9, wherein the patterned copper circuit layer comprises a separated first trace and a second trace, and the resistor element bridges the first trace and the second trace.

12. The power device package according to claim 11, wherein the low-voltage, silicon-based MOS die is die-bonded onto the first trace.

13. The power device package according to claim 7, further comprising:
a gate driver component disposed on the transfer board device.

14. The power device package according to claim 1, wherein the GaN power device comprises an E-Mode GaN HEMT die.

15. The power device package according to claim 1, wherein the frame base island is connected to a heat sink.

16. The power device package according to claim 15, wherein the frame base island, the heat sink, and the drain pin are integrally formed from copper metal.
